(19) United States
(12) Patent Application Publication
(10) Pub. No.: US 2011/0180905 A1
(43) Pub. Date: Jul. 28, 2011

(54) GeSbTe MATERIAL INCLUDING SUPERFLOW LAYER(S), AND USE OF Ge TO PREVENT INTERACTION OF Te FROM SbXTeY AND GeXTeY RESULTING IN HIGH Te CONTENT AND FILM CRYSTALLINITY

(75) Inventors: Jun-Fei Zheng, Westport, CT (US); Jeffrey F. Roeder, Brookfield, CT (US); Philip S.H. Chen, Bethel, CT (US)

(73) Assignee: Advanced Technology Materials, Inc., Danbury, CT (US)

(21) Appl. No.: 12/997,551

(22) PCT Filed: Jun. 8, 2009
(86) PCT No.: PCT/US09/46655

§ 371 Date: Mar. 15, 2011

Related U.S. Application Data
(60) Provisional application No. 61/060,468, filed on Jun. 10, 2008.
(60) Provisional application No. 61/120,332, filed on Dec. 5, 2008.
(60) Provisional application No. 61/177,900, filed on May 13, 2009.

(51) Int. Cl. H01L 29/26; H01L 21/365

(52) U.S. Cl. 257/616; 438/478; 977/755; 257/E29.079; 257/E21.463

(57) ABSTRACT

A multilayer film stack containing germanium, antimony and tellurium that can be annealed to form a GST product material of homogeneous and smooth character, wherein at least one antimony-containing layer is isolated from a tellurium-containing layer by an intervening germanium layer, and the multilayer film stack comprises at least two intervening germanium layers. The multilayer film stack can be formed by vapor deposition techniques such as chemical vapor deposition or atomic layer deposition. The annealable multilayer film stack can be formed in high aspect ratio vias to form phase change memory devices of superior character with respect to the stoichiometric and morphological characteristics of the GST product material.

### CROSS-REFERENCE TO RELATED APPLICATIONS

This application claims priority of U.S. Provisional Patent Application No. 61/177,900 filed May 13, 2009; U.S. Provisional Patent Application No. 61/120,332 filed Dec. 5, 2008; and U.S. Provisional Patent Application No. 61/060,468 filed Jun. 10, 2008. The disclosures of all of said U.S. Provisional Patent Applications are hereby incorporated herein by reference, for all purposes.

### FIELD OF THE INVENTION

The present invention relates to germanium-antimony-tellurium (GeSbTe) materials including one or more superflow layers therein, and to formation of GeSbTe materials of desired stoichiometry and smooth morphology in applications in which tellurium is otherwise susceptible to preferential reaction with antimony or germanium to form GST compositions of undesirable stoichiometry having excessive content of tellurium and crystalline structures.

### DESCRIPTION OF THE RELATED ART

Phase Change Memory (PCM) technology is based on materials that undergo a phase change when heated and are read out as “0” or “1” based on their electrical resistivity, which changes in correspondence to whether the phase change material in the cell is in the crystalline or amorphous phase.

The materials used in PCM applications comprise a large number of binary, ternary, and quaternary alloys of a number of metals and metalloids. Examples include GeSbTe, GeSbInTe, and many others. As used herein, the identification of compounds such as GeSbTe without appertaining stoichiometric coefficients or values will be understood as a general representation of varied compounds containing the specified elements, without regard to specific stoichiometric coefficients and values. For example, the reference to GeSbTe includes Ge₂Sb₂Te₅, as well as all other stoichiometric forms of such compound GeₓSb_{y}Te_{z}, wherein x, y and z are the respective stoichiometric coefficients of germanium, antimony and tellurium.

Germanium-antimony-tellurium alloys are of particular interest for PCM devices due to their desirable phase change properties of such alloys. These alloys, and their elements and sub-alloys, are sometimes hereinafter referred to with first-letter identifications of the respective elements, with the alloy GeₓSb_{y}Te_{z} being referred to as GST, the alloy Sb_{y}Te_{z} being referred to as ST, the alloy GeₓTe_{z} being referred to as GT, the alloy GeₓSb_{y} being referred to as GS, and the individual elements germanium, antimony and tellurium being referred to as G, S and T, respectively.

PCM devices require relatively pure material alloys, with well controlled composition. Current processes for making PCM devices utilize physical vapor deposition to deposit thin films of these materials. As device geometries shrink, the PCM material must be deposited into vias in order to control the phase transition and the necessary heat transfer.

In forming GST-based phase change alloy materials, various fabrication techniques have been employed, including (1) Ge, Sb, and Te co-deposition to form GST material, (2) depositions of alternating GS and ST layers to form a correspondingly layered stack which is then annealed to form a homogenous GST alloy, and (3) deposition of successive Ge, Sb and Te layers in repeated sequence to for a correspondingly layered stacked which is then annealed to form the homogeneous GST alloy.

The latter two approaches involve deposition, by vapor deposition techniques, of respective layers forming a so-called “stack” or “film stack.” The multilayer stack then is subjected to elevated temperature annealing to homogenize the overall material and form a bulk alloy product.

SbTe alloys typically exhibit a low phase change temperature and react readily with Te to form SbTe with higher % Te content when the SbTe alloy is at deposition temperature in the vicinity of 300° C. and additional Te is available. This is encountered, for example, when antimony and tellurium precursors such as tetrakis(dimethylamido)antimony, SbTDMA, and Te(tBu)₂ are employed to deposit antimony and tellurium.

This phenomenon makes the deposition of Ge_{x′}Te_{z′} films on top of Sb_{y}Te_{y} films in a controlled manner as regards the stoichiometry of Te very difficult, since the availability of Te during Ge_{x′}Te_{z′} deposition will promote crystalline film formation, from reaction of Te with Sb to form ST of higher Te content and/or from enhancement of % Te content in Ge_{x′}Te_{z′}. As a result, it has been observed that a smooth Sb_{y}Te_{z} film and a smooth Ge_{x′}Te_{z′} stack can interact to form a rough Sb_{y}Te_{z}/Ge_{x′}Te_{z′} stack, and that tellurium concentration will increase to unsuitably high levels as a result of Sb_{y}Te_{z} film and Ge_{x′}Te_{z′} stack combination.

Similar phenomena will be encountered when Sb_{y}Te_{z} is grown on Ge_{x′}Te_{z′}. For example, a Sb_{y}Te_{z} film containing 20% tellurium coated on a Ge_{x′}Te_{z′} film containing 20% tellurium can interact to form a Sb_{y}Te_{z}/Ge_{x′}Te_{z′} combined layer with more than 40% tellurium. This undesired result is also cumulatively increased when the growth of Ge_{x′}Te_{z′} on Sb_{y}Te_{z} or growth of Sb_{y}Te_{z} on Ge_{x′}Te_{z′} is repeated.

The inability to precisely control tellurium composition in such layered conformations and the rough morphological character of the resulting Sb_{y}Te_{z}/Ge_{x′}Te_{z′} film stack or repeated Sb_{y}Te_{z}/Ge_{x′}Te_{z′ and} stacked layers is a significant issue limiting the utility of the resulting material in applications such as PCM memory devices. In this respect, rough film stacks are undesirable for conformal films having a thickness of 60 nm or less in high aspect ratio cavities.

It would therefore be a significant advance in the art to provide materials and corresponding process methodology that overcome these stoichiometric and morphological problems, and enable formation of GST and similar materials of superior compositional and smooth character to be achieved.

### SUMMARY OF THE INVENTION

The present invention relates to GeSbTe materials including one or more superflow layers therein, and to formation of GeSbTe materials of desired stoichiometry and smooth morphology for applications such as phase change memory devices, and to material containing germanium, antimony and tellurium, which is suitable for annealing without preferential reaction of tellurium with antimony that would otherwise result in undesired stoichiometry and morphological roughness.

In one aspect, the invention relates to a microelectronic device structure including a substrate having an upper surface with a sub-surface feature therein having sidewall and bottom surface areas, and a multilayer film material deposited on the upper surface and sub-surface feature, said multilayer film material comprising a germanium-containing layer, an antimony-containing layer, and a tellurium-containing layer, wherein deposited material thickness of the multilayer film material on at least one of the sidewall and bottom surface areas of the feature is greater than deposited material thickness of the multilayer film material on the upper surface.

In another aspect, the invention relates to a GST film formed on a substrate, the substrate comprising an upper surface and at least one sub-surface feature therein, the feature having at least a base portion and a sidewall portion, and the GST film having a deposited thickness on at least one of the sidewall and base portions that is greater than deposited thickness of the GST film on the upper surface of the substrate.

A further aspect of the invention relates to a process of depositing a GST film, comprising providing a substrate with an upper surface and at least one sub-surface feature therein, the feature having at least a base portion and a sidewall portion; contacting the substrate with vapor phase precursors comprising Ge, Sb and Te; and depositing thereon a GST film, the GST film having a deposited thickness on at least one of the sidewall and the base portions that is greater than deposited thickness of the GST film on the upper surface of the substrate, and wherein the Ge, Sb and Te vapor phase precursors are contacted with the substrate in any order.

Another aspect of the invention relates to a microelectronic device structure made using the aforementioned process.

Yet another aspect of the invention relates to a microelectronic device structure having a sub-surface feature therein, the sub-surface feature comprising germanium, tellurium and antimony, the subsurface feature further comprising at least one superflow layer deposited therein, with a thickness that is greater in a lower portion of the sub-surface feature than in an upper sidewall portion of the sub-surface feature, the superflow layer comprising at least antimony and tellurium.

A further aspect of the invention relates to a microelectronic device structure including a substrate and a sub-subsurface feature in said substrate, with a GST material in said sub-surface feature, including at least one superflow layer in said GST material.

It is noted that as used herein and in the appended claims, the singular forms “a”, “and”, and “the” include plural referents unless the context clearly dictates otherwise.

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved.

The invention is described herein in various embodiments, and with reference to various features and aspects of the invention. The invention contemplates such features, aspects and embodiments in various permutations and combinations, as being within the scope of the invention. The invention may therefore be specified as comprising, consisting or consisting essentially of, any of such combinations and permutations of these specific features, aspects and embodiments, or a selected one or ones thereof.

As used herein, a “superflow layer” is a layer deposited in a sub-surface feature of a substrate having an upper surface with the sub-surface feature therein, wherein the sub-surface feature has sidewall and bottom surface areas, and wherein the deposited layer has greater deposited thickness on a lower portion of the feature, i.e., on at least one of the lower sidewall and bottom surface areas of the feature, than on at least one of an upper sidewall surface of the feature and the upper surface of the substrate. The superflow layer may for example have increasing thickness with increasing depth in the feature.

Other aspects, features and embodiments of the invention will be more fully apparent from the ensuing disclosure and appended claims.

### BRIEF DESCRIPTION OF THE DRAWINGS

FIG. 1 is a photomicrograph of a baseline structure of Ge/SbTe on a substrate, wherein the film contains 16% Ge, 63.6% Sb, and 20.2% Te.

FIGS. 2a, 2b, 3a and 3b illustrate GST conformal deposition in a 100 nm 3:1 aspect ratio oxide trench, in which the composition of the deposited material is 13% Ge, 65% Sb, and 22% Te. Each stack is approximately 110 Å.

FIG. 2a is a photomicrograph showing a four layer stack (Ge/Sb0.75Te0.25/Ge/Sb0.75Te0.25).

FIG. 2b is a photomicrograph showing the GST structure of FIG. 2a, in a 90° view.

FIG. 3a is a photomicrograph showing an eight layer stack comprising a repeat of the four layer stack of FIG. 2a.

FIG. 3b is a photomicrograph showing the GST structure of FIG. 3a, in a 90° view.

FIG. 4 is a photomicrograph showing a GST structure in which very thin Ge layers separate SbTe layers from one another in the stack.

FIG. 5 is a schematic representation of a superflow layer in accordance with the invention, in a via of a substrate.

FIG. 6 is a schematic representation of a conformal layer in a via of a substrate, for comparison with the structure of FIG. 5.

FIG. 7 is a schematic representation of a multi-layer material in a via of a substrate, wherein the multi-layer material includes two superflow layers and one conformal layer.

FIG. 8 is a schematic representation of a multi-layer material in a via of a substrate, including three superflow layers.

FIG. 9 is a photomicrograph showing a SbTe film (Sb 64.2% Te 35.7%) grown on an SiO₂ surfaced trench.

FIG. 10 is a photomicrograph showing a SbTe film (Sb 59% Te 41%) grown on a TiN surfaced trench.

FIG. 11 is a photomicrograph showing a multi-layer film (ST/G/ST/G/ST/G/ST/G) grown on an SiO₂ surfaced trench, having an average composition from the multi-layers of 15.6% Ge, 61.4% Sb, 23% Te.

### DETAILED DESCRIPTION OF THE INVENTION, AND PREFERRED EMBODIMENTS THEREOF

The present invention relates to GeSbTe materials including one or more superflow layers therein, and to associated processes and microelectronic device structures.

The invention also relates to GST materials in which germanium is utilized as an effective barrier material in annealable multilayer film stacks containing germanium, antimony and tellurium, when interposed between antimony-containing layers and tellurium-containing layers in the stack, to prevent antimony/tellurium interaction that would otherwise result in GST product material having undesirable excess tellurium stoichiometry and rough film character rendering it unsuitable for applications such as PCM memory devices. This is surprising, since germanium also is reactive with tellurium to form GeTe, and it would not be expected a priori that stoichiometrically and morphologically superior GST product material would result from such conformation of precursor stack layers.

The invention in one aspect relates to a microelectronic device structure including a substrate having an upper surface with a sub-surface feature therein having sidewall and bottom surface areas, and a multilayer film material deposited on the upper surface and sub-surface feature, said multilayer film material comprising a germanium-containing layer, an antimony-containing layer, and a tellurium-containing layer, wherein deposited material thickness of the multilayer film material on at least one of the sidewall and bottom surface areas of the feature is greater than deposited material thickness of the multilayer film material on the upper surface.

The multilayer film material can be substantially homogenous, and preferably is free of surface perturbations.

The sub-surface feature of the microelectronic device structure can be of any suitable conformation, e.g., having an aspect ratio that is between 1:1 and 5:1, and having a width that is between 10 nm and 100 nm.

In one implementation of the microelectronic device structure, at least one antimony-containing layer of at least two constituting elements in the multilayer film material is isolated from a tellurium-containing layer of at least two constituting elements by an intervening germanium containing layer. The multilayer film material can include layers of varying thickness, having an average Ge concentration of from about 1.0% to 55%; an average Sb concentration of from about 0.01% to about 70%; and an average Te concentration of from about 15% to about 55%. The multilayer film in one embodiment is annealed.

The multilayer film material in such microelectronic device structure can have any suitable layered structure, such as a layered structure selected from the group consisting of:
. . . ST/G/ST/G/ST/G . . . ;
. . . GST/G/GST/G/GST . . . ;
. . . ST/G/GT/G/ST/G/GT/G . . . ;
. . . G/GST/G/GST/G/GST/G . . . ; and
. . . G/ST/G/GT/G/ST/G/GT/G . . . ;

In another implementation, the multilayer film material in the microelectronic device structure contains a series of layers comprising germanium, antimony and tellurium. A further implementation is characterized by the multilayer film containing at least two intervening germanium layers.

The microelectronic device structure in one illustrative embodiment includes an ST layer having a thickness on at least one of the sidewall and bottom areas of the sub-surface feature that is greater than thickness of the ST layer on the upper surface.

The microelectronic device structure advantageously has a smooth morphology.

In another aspect, the invention contemplates a GST film formed on a substrate, the substrate comprising an upper surface and at least one sub-surface feature therein, the feature having at least a base portion and a sidewall portion, and the GST film having a deposited thickness on at least one of the sidewall and base portions that is greater than deposited thickness of the GST film on the upper surface of the substrate. The GST film may contain a series of layers comprising germanium, antimony and tellurium, and may contain at least two intervening germanium layers (the term “intervening” meaning that the germanium layer is interposed between an antimony-containing layer and a tellurium-containing layer.

This GST film may be constituted with at least one antimony-containing layer comprising at least two constituting elements in the GST film that is isolated from a tellurium-containing layer comprising at least two constituting elements in the GST film, by an intervening germanium layer. The GST film can have a layered structure, such as a layered structure selected from the group consisting of:
. . . ST/G/ST/G/ST/G . . . ;
. . . GST/G/GST/G/GST . . . ;
. . . ST/G/GT/G/ST/G/GT/G . . . ;
. . . G/GST/G/GST/G/GST/G . . . ; and
. . . GST/G/GT/G/ST/G/GT/G . . . .

The GST film in one embodiment includes an ST layer having a thickness on at least one of the sidewall and base portions of the sub-surface feature that is greater than the thickness of the ST layer on the upper surface. In another embodiment, the GST film includes a multilayer film having varying layer thickness therein, with an average Ge concentration of from about 1.0% to 55%; an average Sb concentration of from about 0.01% to about 70%; and an average Te concentration of from about 15% to about 55%.

The GST film advantageously has a smooth morphology. Such film advantageously is free of surface perturbations. The GST film may be annealed, and may be substantially homogenous. In an illustrative embodiment, the sub-surface feature of the GST film has an aspect ratio that is between 1:1 and 5:1. The sub-surface feature may for example have a width that is between 10 nm and 100 nm.

The GST film of the invention can be formed by a deposition process, including providing a substrate with an upper surface and at least one sub-surface feature therein, the feature having at least a base portion and a sidewall portion. The process includes contacting the substrate with vapor phase precursors comprising Ge, Sb and Te, and depositing thereon a GST film, wherein the GST film has a deposited thickness on at least one of the sidewall and the base portions that is greater than deposited thickness of the GST film on the upper surface of the substrate, and wherein the Ge, Sb and Te vapor phase precursors are contacted with the substrate in any order.

In the aforementioned process, the vapor deposition can be carried out using germanium methyl amide amidinate (GeMAMDN) as a germanium precursor, tetrakis(dimethylamido)antimony, SbTDMA, as an antimony precursor, and Te(tBu)₂ as a tellurium precursor. Alternatively, each of such precursors may be used as a precursor with other precursors. The vapor deposition process can be of any suitable type, and can for example comprise a vapor deposition process selected from the group consisting of chemical vapor deposition, atomic layer deposition and digital chemical vapor deposition.

The process can be carried out wherein the GST film contains a series of layers with at least one layer constituting at least two of the elements selected from the group consisting of germanium, antimony and tellurium. The GST film can have a smooth morphology, and it can be homogenous. The film can be annealed at least once. The film advantageously is free of surface perturbations. The film can comprise a multi-layer structure.

In one embodiment, the process is carried out wherein the GST film contains at least two intervening germanium layers.

In an illustrative implementation of the vapor deposition process, the GST film is a multilayer film having varying layer thickness in the multilayer film, and having an average Ge concentration of from about 1.0% to 55%; an average Sb concentration of from about 0.01% to about 70%; and an average Te concentration of from about 15% to about 55%.

The sub-surface feature in the vapor deposition process can be of any suitable conformation and dimensions. In one embodiment, it has an aspect ratio that is between 1:1 and 5:1,. and a width that is between 10 nm and 100 nm.

When the GST film comprises a multi-layer structure, the process conditions can for example include a deposition temperature between 240° C. and 350° C. The deposition of the multi-layer structure is advantageously carried out in a deposition chamber, at deposition chamber pressure between 0.5 Torr and 20 Torr.

The invention thus provides a microelectronic device structure made using the aforementioned process.

A microelectronic device structure according to the invention, in one aspect thereof, includes a sub-surface feature therein. The sub-surface feature comprises germanium, tellurium and antimony. The subsurface feature further comprises at least one superflow layer deposited therein, with a thickness that is greater in a lower portion of the sub-surface feature than in an upper sidewall portion of the sub-surface feature, and the superflow layer comprises at least antimony and tellurium.

Such microelectronic device structure can further comprise at least one germanium-containing layer. The microelectronic device structure can be fabricated so that the at least one superflow layer and the at least one germanium-containing layer are in series. The germanium-containing layer can be conformal. The at least one superflow layer in one embodiment has a thickness that is greater in a base portion of the sub-surface feature than in an upper sidewall portion of the sub-surface feature. The at least one superflow layer in another embodiment has a thickness that is greater in a lower sidewall portion of the sub-surface feature than in an upper sidewall portion of the sub-surface feature. The microelectronic device structure may have one, or alternatively at least two superflow layers.

In one illustrative embodiment, the microelectronic device structure includes a series of layers, e.g., a series selected from the group consisting of:
. . . ST/G/ST/G/ST/G . . . ;
. . . GST/G/GST/G/GST . . . ;
. . . ST/G/GT/G/ST/G/GT/G . . . ;
. . . G/GST/G/GST/G/GST/G . . . ; and
. . . G/ST/G/GT/G/ST/G/GT/G . . .

The microelectronic device structure in one embodiment includes at least two germanium-containing layers. Such at least two germanium-containing layers may be conformal in character.

The microelectronic device structure itself may have a smooth morphology. The structure may have varying layer thickness in the superflow layer and an average antimony concentration of from about 0.01% to about 70%, and an average tellurium concentration of from about 15% to about 55%.

In the broad practice of the invention, the microelectronic device structure can have a series of superflow layers, of varying layer thickness therein, with an average germanium concentration of from about 1.0% to about 55%, an average antimony concentration of from about 0.01% to about 70%, and an average tellurium concentration of from about 15% to about 55%.

The series of layers in the microelectronic device structure may be annealed in one implementation of the invention. In another embodiment, the series of layers is substantially homogenous.

In various embodiments of the microelectronic device structure of the invention, the sub-surface feature may have an aspect ratio that is between 1:1 and 5:1, and a width that is between 10 nm and 100 nm. The series of layers in specific embodiments may be free of surface perturbations.

In the fabrication of the series of layers, vapor deposition techniques can be employed, with suitable precursors, e.g., using germanium methyl amide amidinate (GeMAMDN) as a germanium precursor, tetrakis(dimethylamido)antimony, SbTDMA, as an antimony precursor, and Te(tBu)₂ as a tellurium precursor. The at least one superflow layer in the device structure may be deposited by a vapor deposition process.

In other variations, the microelectronic device structure may include at least one superflow layer, with such superflow layer and the at least one germanium containing layer being deposited by a vapor deposition process, e.g., a process selected from the group consisting of chemical vapor deposition, atomic layer deposition and digital chemical vapor deposition. The vapor deposition process can be plasma enhanced. The microelectronic device structure may have a form including at least one germanium layer, wherein the at least one germanium-containing layer is vapor deposited from germanium methyl amide amidinate (GeMAMDN). The microelectronic device structure may have a form including at least one superflow layer, wherein the superflow layer is vapor deposited from tetrakis(dimethylamido)antimony, SbTDMA, and Te(tBu)₂. The microelectronic device structure may be fabricated with a series of layers, wherein the series of layers is annealed at least once. The series of layers may comprise a multi-layer structure, and may be vapor deposited at temperature between 240° C. and 350° C., with the vapor deposition being carried out in a deposition chamber, wherein the deposition pressure is between 0.5 Torr and 20 Torr.

A further aspect of the invention relates to a microelectronic device structure including a substrate and a sub-subsurface feature in said substrate, with a GST material in the sub-surface feature, including at least one superflow layer in the GST material. Such microelectronic device structure may be fabricated with at least one germanium layer in the GST material arranged to suppress deleterious interaction of Sb and Te.

The use of germanium isolation layers in the films and device structures constitutes a further aspect of the invention for avoidance of issues of tellurium content and film crystallinity that would otherwise arise due to interaction of Sb and Te.

The invention therefore contemplates a multilayer film stack containing germanium, antimony and tellurium that is annealable to form a GST product material of homogeneous and smooth character, wherein at least one antimony-containing layer is isolated from an otherwise adjacent tellurium-containing layer by an intervening germanium layer.

The invention further contemplates a method of forming a multilayer film stack containing germanium, antimony and tellurium that is annealable to form a GST product material of homogeneous and smooth character, such method comprising depositing successive layers to form the multilayer stack, wherein at least one antimony-containing layer is isolated from an otherwise adjacent tellurium-containing layer by an intervening germanium layer.

In the general practice of the present invention, a thin germanium layer can be used to isolate antimony-containing and tellurium-containing layers, e.g., Sb, Te and SbTe layers, to avoid preferential reaction of tellurium with antimony in adjacent layers that would otherwise produce Sb_{y}Te_{z} wherein z is a higher than desired stoichiometric value. By using germanium to isolate SbTe from tellurium-containing layers, it is possible to control the film stack formation process to achieve a desired composition in a layer-controlled manner, and to avoid formation of rough product films due to high tellurium concentrations resulting from reaction of antimony with tellurium in adjacent layers.

Annealable film stacks prepared in accordance with the present invention may be of any suitable type, wherein a germanium isolation layer is interposed between an antimony-containing layer and a tellurium-containing layer that would otherwise react with one another to form an antimony-tellurium alloy containing tellurium in excess of a desirable stoichiometric value for GST applications such as phase change memory devices.

By way of example, annealable multilayer film stacks in accordance with the present invention may include, without limitation, stacks of the following composition, wherein the interface between successive layers in the stack is indicated by a “/” notation, wherein repeating layer structure is indicated by “. . . ”, and wherein germanium, antimony and tellurium are identified in single-letter notation as G, S, and T, respectively.

Illustrative multilayer film stack compositions include the following:
. . . G/ST/G/ST/G/ST . . .
. . . ST/G/ST/G/ST/G . . .
. . . ST/G/GT/G/ST/G/GT/G . . .
. . . ST/G/GT/G/GT/G/ST/ST/G/GT/G/GT/G . . .
. . . ST/G/T/G/ST/G/T/G . . .
. . . S/G/T/G/S/G/T/G/S/G/T/G/S/G/T/G/S/G . . .

As a further example illustrating the advantage of utilizing germanium as a barrier material against undesired access and reaction of tellurium with antimony, a multilayer film stack, of the composition . . . ST/G/ST/G/ST . . . , was formed by vapor deposition at 300° C. and 7 torr pressure, using germanium methyl amide amidinate (GeMAMDN) as the germanium precursor, tetrakis(dimethylamido)antimony, SbTDMA, as the antimony precursor, and Te(tBu)₂ as the tellurium precursor. A multilayer film stack was concurrently formed using the same germanium, antimony and tellurium precursors, at the same temperature and pressure conditions, having the composition . . . ST/GT/ST/GT/ST . . . , for comparison purposes. In such stacks, the starting material may be either Ge or ST.

This comparison showed that the ST/G/ST/G/ST . . . multilayer structure when annealed and homogenized formed a GST product film that was of a smooth homogeneous character, in contrast to the rough product film produced by the . . . ST/GT/ST/GT/ST . . . multilayer structure.

Various GST film formation runs utilizing . . . ST/G/ST/G . . . multilayer structures formed from the aforementioned precursors were conducted, on the following substrates: planar SiO₂ on silicon wafer, on TiAlN on silicon wafer, and SiO₂ wafer with 100 nm wide and 250 nm deep trenches. Extremely smooth Ge/SbTe repeating stack films were achieved, with highly conformal deposition on the SiO₂ trench. The composition achieved in such manner in one embodiment may comprise about 10%-15% germanium, 60%-70% antimony and 20%-30% tellurium. Again, the multilayer structures may start with Ge or ST material.

In a further aspect, the invention relates to a multilayer film stack containing germanium, antimony and tellurium, wherein at least one antimony-containing layer is isolated from a tellurium-containing layer by an intervening germanium layer, and the multilayer film stack comprises at least two intervening germanium layers.

Such multilayer film stack may be of any appropriate composition for the intended use, and may for example have a layer structure selected from among the following:
. . . G/ST/G/ST/G/ST . . .
. . . ST/G/ST/G/ST/G . . . ;
. . . GST/G/GST/G/GST . . . ;
. . . ST/G/GT/G/ST/G/GT/G . . . ,
   containing 1.0%-55% germanium, 0.01%-70% antimony and 15%-55% tellurium.

The multilayer film stack can be deposited in a via, trench or cavity constituting a sub-surface feature of the substrate. Additionally, or alternatively, the multilayer film stack can be deposited on the surface of such substrate. In one embodiment, the multilayer film stack is deposited on a substrate and/or in a feature of the substrate, wherein the substrate has a surface and at least one feature with sidewalls, e.g., a via, trench or cavity. The multilayer film stack in such application may as previously discussed have a thickness that is greater on the sidewall than on the substrate surface.

The layers in the multilayer film stack may have any suitable thickness, e.g., a thickness in a range of from about 20 to about 1000 Å. The multilayer film stack may comprise more than two intervening germanium layers, such as 2 to 8 such intervening germanium layers.

Multilayer film stacks of the invention can be formed in any suitable manner. Most preferably, such multilayer film stacks are formed by a vapor deposition process selected from among CVD and ALD.

The invention thus contemplates a GST material comprising the multilayer film stack, wherein the multilayer film stack is annealed and/or homogenized. The GST material may be deposited on a surface of a microelectronic device structure, and/or in a sub-surface feature, e.g., a hole, in such surface.

GST materials of the invention can be utilized in fabricating a variety of GST microelectronic devices including phase change memory devices.

The invention in another aspect involves a method of forming a multilayer film stack containing germanium, antimony and tellurium, including depositing successive layers to form the multilayer film stack, wherein at least one antimony-containing layer is isolated from a tellurium-containing layer by an intervening germanium layer, and the multilayer film stack comprises at least two intervening germanium layers. Such multilayer film stack can have a layer structure such as:
. . . G/ST/G/ST/G/ST . . .
. . . ST/G/ST/G/ST/G . . . ;
. . . GST/G/GST/G/GST . . . ;
. . . ST/G/GT/G/ST/G/GT/G . . . ; or
. . . S/G/T/G/S/G/T/G/S/G/T/G/S/G/T/G/S/G . . . .

The multilayer film stack in such stack arrangements can have any suitable composition of G, S and T components, such as a composition of 1.0%-55% germanium, 0.01 to 70% antimony and 15%-55% tellurium. The multilayer film stack may be deposited in a via, trench or cavity of a substrate and/or on a substrate. The substrate may for example have a surface and at least one feature with sidewalls, such as a via, trench or cavity. The multilayer film stack in one embodiment of such structure has a thickness that is greater on the sidewall of the subsurface feature than on the substrate surface.

The individual thicknesses of the component layers in the multilayer film stack may be widely varied, and may be the same as, or different from, one another. The respective layers of the stack may for example be deposited with a thickness in a range of from about 20 to about 1000 Å. The successive layers may comprise two or more than two intervening germanium layers, in various embodiments of the invention.

The precursors used for deposition of the respective G, S and T components may likewise be widely varied in the broad practice of the invention. In one illustrative embodiment, the precursors are deposited by vapor deposition involving contacting a substrate with vapor of precursors including germanium methyl amide amidinate (GeMAMDN) as the germanium precursor, tetrakis(dimethylamido)antimony, SbTDMA, as the antimony precursor, and Te(tBu)₂ as the tellurium precursor.

The vapor deposition may be carried out at any suitable conditions, such as temperature in a range of from 160° C. to 400° C., pressure in a range of from 0.5 to 20 torr, and more specifically in a range of from 2.5 to 8 torr.

The invention therefore encompasses forming a GST material by a method including forming a multilayer film stack containing germanium, antimony and tellurium as described herein, and processing said multilayer film stack by at least one of annealing and homogenizing, during a device manufacturing step, or during device operation. Such method may be employed for fabricating a phase change memory device, comprising forming the GST material on and/or in a substrate, e.g., in a hole in the substrate.

A further aspect of the invention relates to an atomic layer deposition method of forming a multilayer film stack containing germanium, antimony and tellurium, the multilayer film stack having a smooth character, said method comprising depositing successive mono-layers to form the multilayer stack, wherein at least one antimony-containing layer is isolated from a tellurium-containing layer by an intervening germanium layer, and the multilayer film stack comprises at least two intervening germanium layers. The stack may contain more than two intervening germanium layers, e.g., from 2 to 8 layers. In one embodiment, the multilayer film stack has a layer structure comprising.
. . . S/G/T/G/S/G/T/G/S/G/T/G/S/G/T/G/S/G . . .
   wherein the starting layer could be S or G and T.

In another embodiment, the multilayer film stack has a layer structure selected from the group consisting of
. . . G/ST/G/ST/G/ST . . . ;
. . . ST/G/ST/G/ST/G . . . ;
GST/G/GST/G/GST . . . ; and
ST/G/GT/G/ST/G/GT/G . . . .

Particularly preferred layer structures useful in the practice of the invention include:
. . . G/ST/G/ST/G/ST . . . ,
. . . GST/G/GST/G/GST . . . ,
. . . G/GST/G/GST/ . . . ,
. . . ST/G/GT/G/ST/G/GT/G . . . ,
. . . S/G/T/G/S/G/T/G/S/G/T/G/S/G/T/G/S/G . . . .

The aforementioned atomic layer deposition method may further comprise annealing the multilayer film stack, in the production of a multilayer film stack having a homogeneous character.

A further aspect of the invention relates to a chemical vapor deposition method of forming a multilayer film stack containing germanium, antimony and tellurium, in which the multilayer film stack has a smooth character. The method involves depositing successive mono-layers to form the multilayer stack, wherein at least one antimony-containing layer is isolated from a tellurium-containing layer by an intervening germanium layer, and the multilayer film stack comprises at least two intervening germanium layers. Such CVD-formed stack may contain any suitable number of intervening germanium layers, e.g., between 2 and 8 intervening germanium layers.

Such CVD methodology may be employed to form a multilayer film stack having a layer structure selected from the group consisting of:
. . . G/ST/G/ST/G/ST . . .
. . . ST/G/ST/G/ST/G . . . ;
. . . GST/G/GST/G/GST . . . ;
. . . ST/G/GT/G/ST/G/GT/G . . . ; and
. . . S/G/T/G/S/G/T/G/S/G/T/G/S/G/T/G/S/G . . . .

The CVD-formed stack following deposition may be annealed, in the production of a multilayer film stack having a homogenous character.

The method of the invention may be employed to form a variety of microelectronic devices and device precursors, e.g., a microelectronic device structure including a substrate having an upper surface with a sub-surface feature therein having sidewall and bottom surface areas, and a multilayer film material deposited on the upper surface and sub-surface feature. Such multilayer film material contains germanium, antimony and tellurium, wherein at least one antimony-containing layer in the multilayer film material is isolated from a tellurium-containing layer by an intervening germanium layer. In one embodiment of such device structure, the deposited material thickness of the multilayer film material on at least one of the sidewall and bottom areas of the feature is greater than deposited material thickness of the multilayer film material on the upper surface.

The microelectronic device structure in such implementation may have any suitable layer structure, such as a layer structure selected from the group consisting of:
. . . G/ST/G/ST/G/ST . . .
. . . ST/G/ST/G/ST/G . . . ;
. . . GST/G/GST/G/GST . . . ;
. . . ST/G/GT/G/ST/G/GT/G . . . ; and
. . . S/G/T/G/S/G/T/G/S/G/T/G/S/G/T/G/S/G . . . .
   The multilayer film material in such microelectronic device structure may contain a series of layers comprising germanium, antimony and tellurium, and may contain at least two intervening germanium layers, e.g., between 2 and 8 intervening germanium layers.

A further aspect of the invention relates to a GST multilayer film stack having: a smooth morphology; a Ge concentration of from about 1.0% to 55%; an Sb concentration of from about 0.01% to about 70%; and a Te concentration of from about 15% to about 55%. Such GST film stack may have at least one antimony-containing layer isolated from an otherwise adjacent tellurium-containing layer by an intervening germanium layer therebetween. The film stack may be annealed, and homogeneous.

In another embodiment of the invention, a process of depositing a GST film, a substrate is provided, with an upper surface and at least one sub-surface feature therein, with the feature having at least a base portion and a sidewall portion. The substrate is contacted with vapor phase precursors comprising Ge, Sb and Te, and a GST film is deposited thereon, with the GST film having a deposited thickness on at least one of the sidewall and the base that is greater than deposited thickness of the GST film on the upper surface of the substrate. The Ge, Sb and Te vapor phase precursors are contacted with the substrate in any order.

An additional aspect of the invention relates to a GST film formed on a substrate, wherein the substrate comprises an upper surface and at least one sub-surface feature therein, with the feature having at least a base portion and a sidewall portion, and the GST film having a deposited thickness on at least one of the sidewall and base portions that is greater than deposited thickness of the GST film on the upper surface of the substrate.

As discussed, the G, S and T precursors employed for forming GST films and materials of the invention may be of any suitable type having appropriate volatilization, transport and decomposition characteristics for ensuring the formation of GST films and materials of a desired character. One preferred combination of G, S and T precursors includes germanium methyl amide amidinate (GeMAMDN) as a germanium precursor, tetrakis(dimethylamido)antimony, SbTDMA, as an antimony precursor, and Te(tBu)₂ as a tellurium precursor.

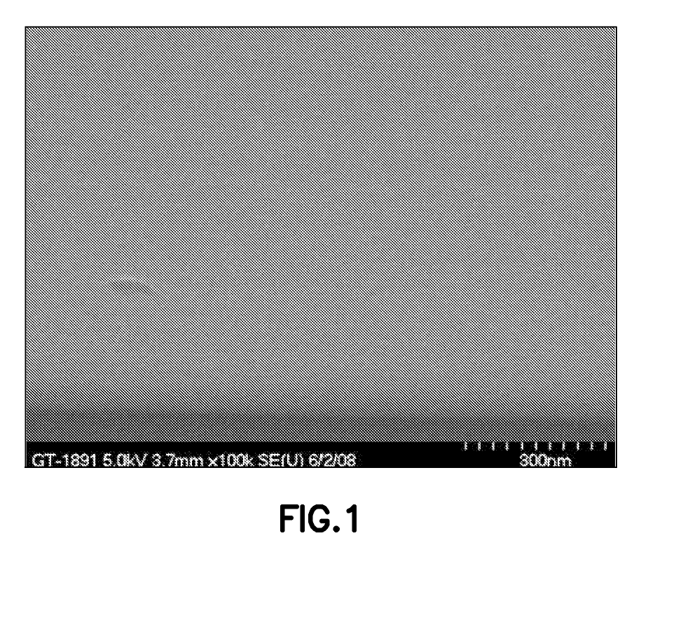

Referring now to the drawings, FIG. 1 is a photomicrograph of a baseline structure of Ge/SbTe on a substrate, wherein the film contains 16% Ge, 63.6% Sb, and 20.2% Te.

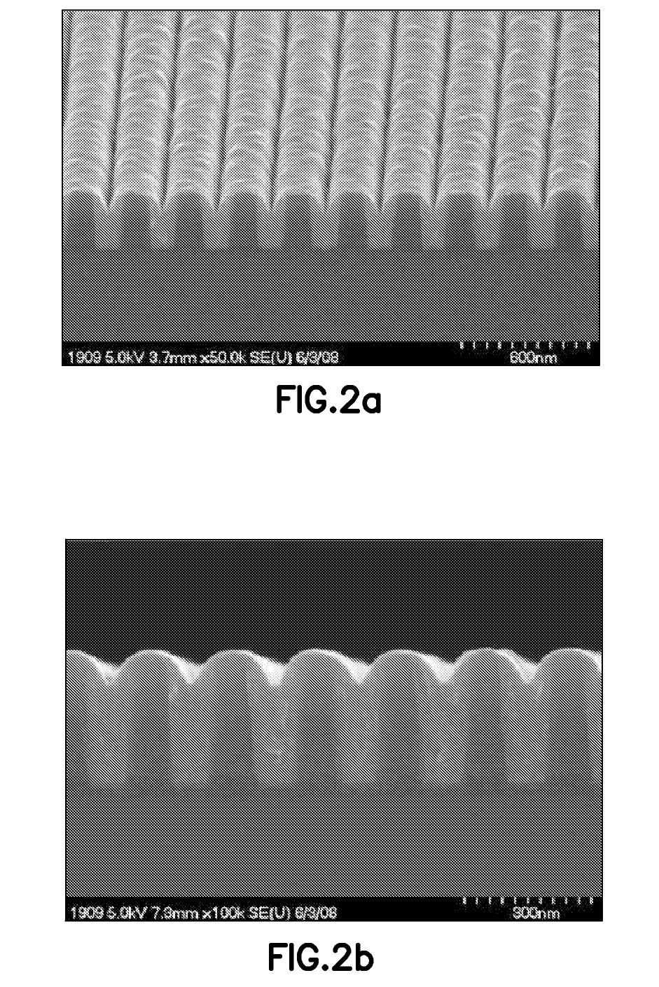

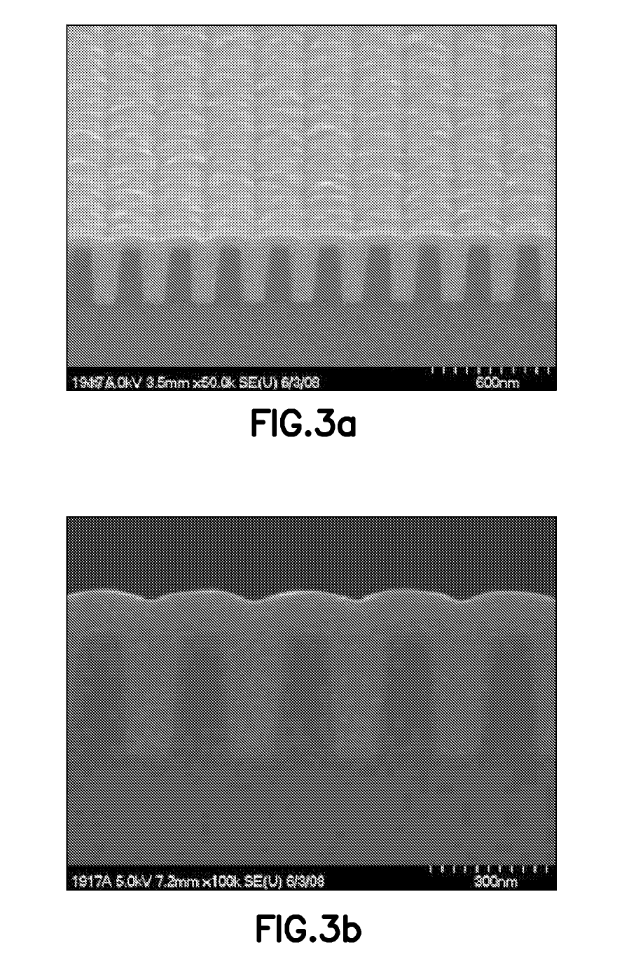

FIGS. 2a, 2b, 3a and 3b illustrate GST conformal deposition in a 100 nm 3:1 aspect ratio oxide trench, in which the composition of the deposited material is 13% Ge, 65% Sb, and 22% Te. Each stack is approximately 110 Å.

FIG. 2a is a photomicrograph showing a four layer stack (Ge/Sb0.75Te0.25/Ge/Sb0.75Te0.25).

FIG. 2b is a photomicrograph showing the GST structure of FIG. 2a, in a 90° view.

FIG. 3a is a photomicrograph showing an eight layer stack comprising a repeat of the four layer stack of FIG. 2a.

FIG. 3b is a photomicrograph showing the GST structure of FIG. 3a, in a 90° view.

In trench or hole deposition of GST precursor material in accordance with the invention, it was observed that the fill of the cavity had a non-conventional fill characteristic, in which the thickness of the deposited material on the sidewall and bottom of the feature were increased compared to the upper surface of the patterned area. In contrast, perfectly conformal films have equal thicknesses on the top, sides and bottoms of patterned features. Further, deviations from the ideal case are conventionally observed that are opposite to the coating thickness characteristics achieved in the practice of the present invention, i.e., the thickness of the deposited film in conventional practice is typically thinner on the sidewall and thicker on the top of the patterned feature. This characteristic differentiates the multilayer film of the invention, when deposited in a sub-surface feature of a substrate, e.g., a via, trench, cavity, hole, or the like.

It is also been found that the formation of the multilayer film stack with a starting layer of Sb_{y}Te_{z} followed by a germanium barrier layer, in repeated Ge/SbTe or SbTe/Ge layer structures, produces good adhesion of the filled structure to the underlying base structure. This has been corroborated with scanning electron micrographs of product structures, showing no evidence of delamination of the filled structure from the underlying base structure.

The thickness of the germanium isolation layer and other layers in the annealable material may be of any suitable thickness. In various embodiments of the invention, these layers can have a thickness in a range of from about 20 to about 100 Å.

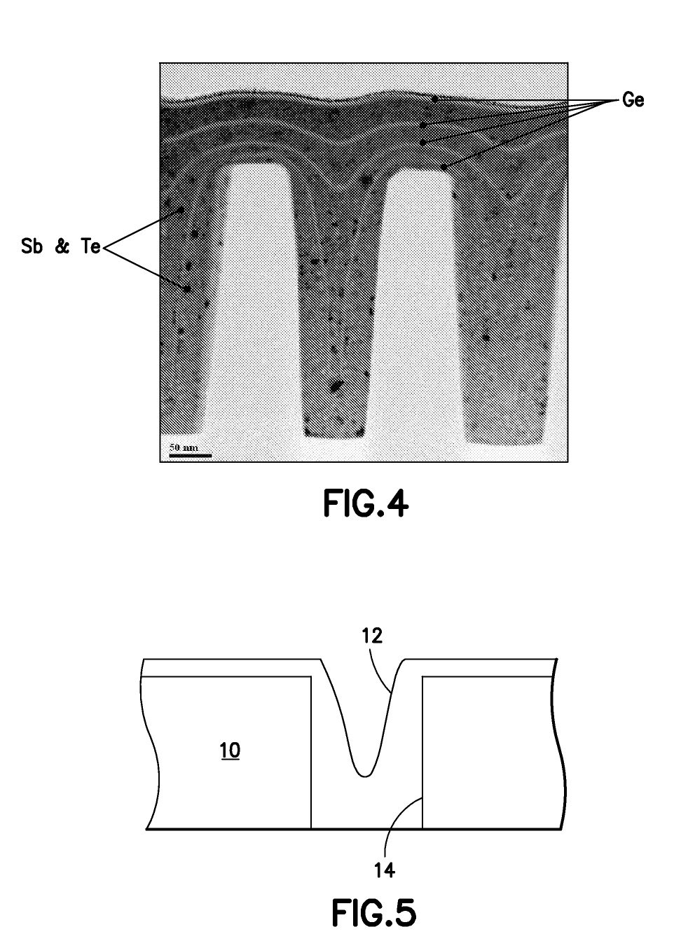

FIG. 4 is a photomicrograph showing a GST structure in which such thin Ge layers separate SbTe layers from one another in the stack.

FIG. 5 is a schematic representation of a superflow layer 12 in accordance with the invention, in a via 14 of a substrate 10.

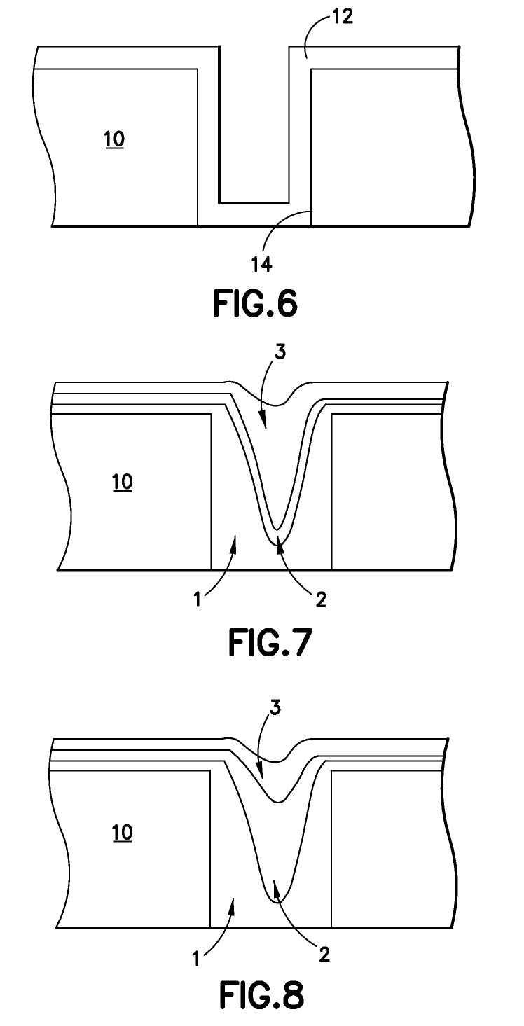

FIG. 6 is a schematic representation of a conformal layer 12 in a via 14 of a substrate 10, for comparison with the structure of FIG. 5.

FIG. 7 is a schematic representation of a multi-layer material in a via of a substrate 10, wherein the multi-layer material includes two superflow layers 1 and 3, and one conformal layer 2.

FIG. 8 is a schematic representation of a multi-layer material in a via of a substrate 10, including three superflow layers 1, 2 and 3.

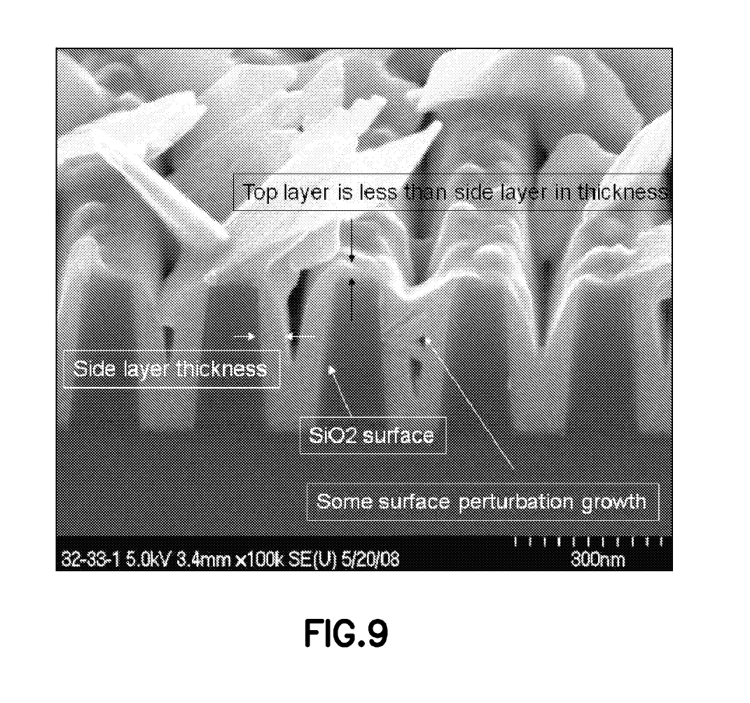

FIGS. 9-11 illustrate superflow layer structures in accordance with the invention.

FIG. 9 is a photomicrograph showing a SbTe film (Sb 64.2% Te 35.7%) grown on an SiO₂ surfaced trench. Note that the superflow growth can lead to random surface growth.

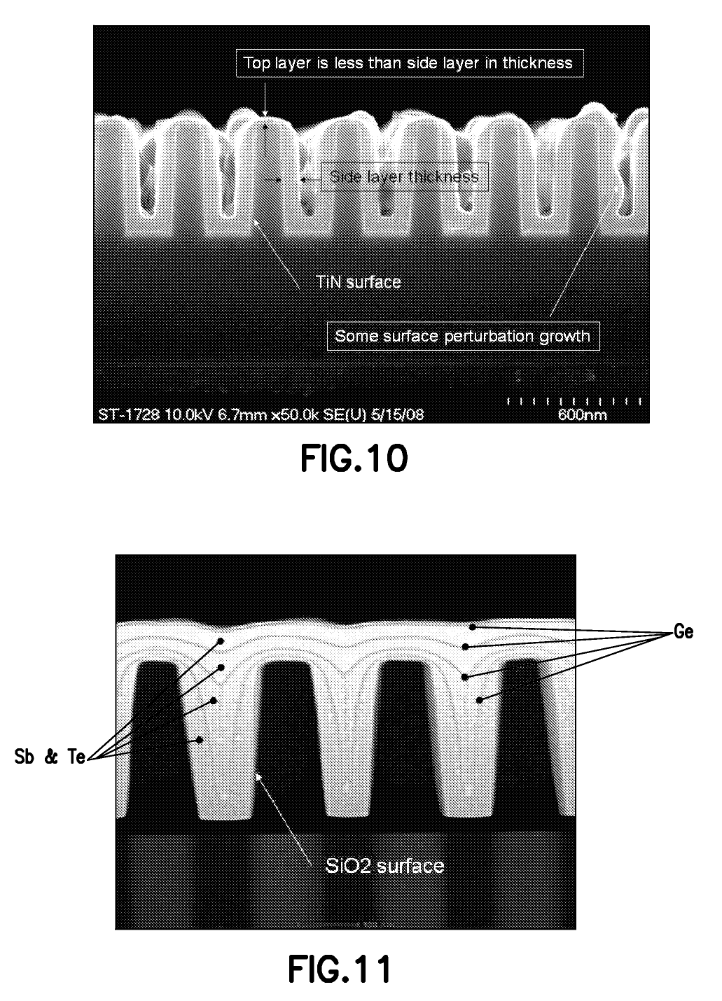

FIG. 10 is a photomicrograph showing a SbTe film (Sb 59% Te 41%) grown on a TiN surfaced trench. Note that the superflow growth can lead to random surface growth.

FIG. 11 is a photomicrograph showing a multi-layer film (ST/G/ST/G/ST/G/ST/G) grown on an SiO₂ surfaced trench, having an average composition from the multi-layers of 15.6% Ge, 61.4% Sb, 23% Te. By inserting the Ge layer in between ST layers, very controlled superflow growth can be achieved, because the intervening Ge isolates the potential accumulation of Sb and Te through surface mobility effects.

Deposition processes that can be utilized to deposit the respective G, S and T components in the practice of the invention, to form the material that is annealed and homogenized to form the GST product material, can be of any suitable type. Vapor deposition processes such as chemical vapor deposition or physical vapor deposition may be employed, utilizing suitable source materials for the respective G, S and T components. In various embodiments, chemical vapor deposition or atomic layer deposition may be usefully employed to deposit the respective components of the material that is subsequently processed to yield the GST product material.

In the use of chemical vapor deposition or atomic layer deposition, any suitable precursor materials for the respective G, S and T components can be used. Precursors of widely varying type are known for these G, S and T components, and the specific precursors can be selected, within the skill of the art, based on the disclosure herein, to provide precursors that are appropriately volatilized and transported to the deposition chamber containing the substrate on which the GST material is to be formed, at the conditions to be utilized for the specific deposition process.

The deposition process thus can be carried out at any suitable conditions of temperature, pressure, flow rate, composition, etc., as are determinable within the skill in the art, e.g., by empirical runs in which appropriate parameters are adjusted to determine a desirable set of process conditions for the deposition.

By way of illustration, deposition of ST, GT and G in a specific embodiment is carried out at temperature of 300° C. and 7 torr pressure. In another embodiment, the germanium deposition is conducted at temperature of 160° C., and the GT and ST deposition is carried out at 280° C. It will be recognized that the specific process conditions are dependent on a number of process parameters, including the amount of the reagent that is used for the deposition process. In general, with higher precursor delivery rate or higher pressure, deposition temperature can be reduced. In still other embodiments involving multi-layer deposition of amorphous GST, temperature in a range of from 200° C. to 400° C., and pressure in a range of from 2.5 to 8 torr, are employed. In further embodiments, temperature above 400° C. is employed.

In the formation of GST in via, cavity or trench structures, the use of germanium isolation layer(s) in the deposited material is of substantial benefit in achieving highly conformal deposition and full fill of the corresponding void volume. The holes in which the multilayer material is formed may be of widely varying geometry. In one embodiment, the holes may be on the order of 60 nm in diameter, and 240 nm deep, in the substrate.

Once the multilayer film stack is deposited, it may be converted to product GST by annealing and homogenization steps of suitable character, carried out in a manner readily determinable by those of ordinary skill in the art, based on the disclosure herein.

Thus, the invention provides an effective multilayer material including at least one germanium isolation layer that may be useful in maintaining ST layer thickness below levels susceptible to undesirable crystalline film formation, and is effective to suppress preferential reaction of antimony and available tellurium. The resulting GST films obtainable from such annealable multilayer material, comprising at least one germanium isolation layer between and in contact with an antimony-containing layer and a tellurium-containing layer, are of superior stoichiometric and morphological character, in relation to GST films formed without use of such germanium isolation layer(s).

The invention therefore provides in various embodiments a multilayer film stack containing germanium, antimony and tellurium that is annealable to form a GST product material of homogeneous and smooth character, wherein at least one antimony-containing layer is isolated from an otherwise adjacent tellurium-containing layer by an intervening germanium layer. The multilayer film stack in various embodiments includes a multiplicity of such germanium isolation layers intermediate successive antimony-containing layers and tellurium-containing layers along the stack.

The multilayer film stack can for example include a layer structure selected from among the following:
. . . G/ST/G/ST/G/ST . . .
. . . ST/G/ST/G/ST/G . . .
. . . ST/G/GT/G/ST/G/GT/G . . .
. . . ST/G/GT/G/GT/G/ST/ST/G/GT/G/GT/G . . .
. . . ST/G/T/G/ST/G/T/G . . .
. . . S/G/T/G/S/G/T/G/S/G/T/G/S/G/T/G/S/G . . .

The multilayer film stack may for example have a composition of 10%-15% germanium, 60%-70% antimony and 20%-30% tellurium. The stack may be deposited, e.g., by a vapor deposition process, in a via, trench or cavity of a substrate. Layers of the multilayer film stack may have a thickness in a range of from about 20 to about 100 Å.

The multilayer film stack can be processed by annealing and homogenization to form a GST material, e.g., of a phase change memory device. For such purpose, the GST material and its predecessor multilayer film stack can be deposited in a hole in the substrate.

The invention correspondingly contemplates a method of forming a multilayer film stack containing germanium, antimony and tellurium that is annealable to form a GST product material of homogeneous and smooth character, wherein the method includes depositing successive layers to form the multilayer stack, wherein at least one antimony-containing layer is isolated from an otherwise adjacent tellurium-containing layer by an intervening germanium layer.

The method may be carried out with the multilayer stack having a layer structure selected from among those previously described, with a germanium, antimony and tellurium composition as also previously described. The successive layers of the multilayer stack may be formed by depositing such layers in a via, trench or cavity of a substrate, and each of the successive layers may have a thickness in a range of from about 20 to about 100 Å.

The deposition of the successive layers may be carried out by vapor deposition, using germanium methyl amide amidinate (GeMAMDN) as the germanium precursor, tetrakis(dimethylamido)antimony, SbTDMA, as the antimony precursor, and Te(tBu)₂ as the tellurium precursor. The deposition of successive layers may be carried out by vapor deposition at temperature in a range of from 160° C. to 400° C., or alternatively a temperature in excess of 400° C., and the deposition may be carried out at pressure in a range of from 2.5 to 8 torr.

The invention further contemplates a method of forming a GST material, comprising forming a multilayer film stack containing germanium, antimony and tellurium as previously described, and annealing and homogenizing same to form the GST material. The GST material may be formed on a substrate to fabricate a phase change memory device, e.g., with the multilayer film stack formed in a hole on the substrate.

Although the invention is described with reference to varied aspects, features and embodiments, in specific described arrangements, it is intended that the invention be correspondingly broadly construed to encompass combinations and permutations of various aspects, features and embodiments in arrangements other than those expressly set forth herein. It therefore is to be understood that the invention may reside, in specific arrangements, as comprising any of the specific aspects, features and embodiments, in sub-combinations and super-combinations thereof.

### INDUSTRIAL APPLICABILITY

The GeSbTe materials, structures and processes of the present invention have utility in the manufacture of microelectronic products such as phase change memory devices.

While the invention has been has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1.-77. (canceled)

78. A microelectronic device structure including a substrate having an upper surface with a subsurface feature therein having sidewall and bottom surface areas, and a multilayer film material deposited on the upper surface and sub-surface feature, said multilayer film material comprising a germanium-containing layer, an antimony-containing layer, and a tellurium-containing layer, wherein deposited material thickness of the multilayer film material on at least one of the sidewall and bottom surface areas of the feature is greater than deposited material thickness of the multilayer film material on the upper surface.

79. The microelectronic device structure of claim 78, characterized by at least one of compatible characteristics selected from the group consisting of:
(a) at least one antimony containing layer of at least two constituting elements in the multilayer film material being isolated from a tellurium containing layer of at least two constituting elements by an intervening germanium containing layer;
(b) the multilayer film material having a layered structure selected from the group consisting of:
. . . ST/G/ST/G/ST/G . . . ;
. . . GST/G/GST/G/GST . . . ;
. . . ST/G/GT/G/ST/G/GT/G . . . ;
. . . G/GST/G/GST/G/GST/G . . . ; and
. . . G/ST/G/GT/G/ST/G/GT/G . . . ;
(c) the multilayer film material containing a series of layers comprising germanium, antimony and tellurium.
(d) the multilayer film material containing at least two intervening germanium layers;
(e) an ST layer having a thickness on at least one of the sidewall and bottom areas of the sub-surface feature that is greater than thickness of the ST layer on the upper surface;
(f) a smooth morphology;
(g) being annealed;
(h) being substantially homogenous;
(i) the sub-surface feature having an aspect ratio that is between 1:1 and 5:1;
(j) the sub-surface feature having a width that is between 10 nm and 100 nm; and
(k) the multilayer film being free of surface perturbations.

80. The microelectronic device structure of claim 78, with at least one antimony containing layer of at least two constituting elements in the multilayer film material being isolated from a tellurium containing layer of at least two constituting elements by an intervening germanium containing layer having varying layer thickness in the multilayer film material, and having an average Ge concentration of from about 1.0% to 55%; an average Sb concentration of from about 0.01% to about 70%; and an average Te concentration of from about 15% to about 55%.

81. A GST film formed on a substrate, the substrate comprising an upper surface and at least one sub-surface feature therein, the feature having at least a base portion and a sidewall portion, and the GST film having a deposited thickness on at least one of the sidewall and base portions that is greater than deposited thickness of the GST film on the upper surface of the substrate.

82. The GST film of claim 81, characterized by at least one of compatible characteristics selected from the group consisting of:
(a) having at least one antimony-containing layer comprising at least two constituting elements in the GST film that is isolated from a tellurium-containing layer comprising at least two constituting elements in the GST film, by an intervening germanium layer;
(b) the GST film material having a layered structure selected from the group consisting of:
. . . ST/G/ST/G/ST/G . . . ;
. . . GST/G/GST/G/GST . . . ;
. . . ST/G/GT/G/ST/G/GT/G . . . ;
. . . G/GST/G/GST/G/GST/G . . . ; and
. . . G/ST/G/GT/G/ST/G/GT/G . . . ;
(c) the GST film material containing a series of layers comprising germanium, antimony and tellurium.
(d) the GST film material containing at least two intervening germanium layers;
(e) an ST layer having a thickness on at least one of the sidewall and bottom areas of the sub-surface feature that is greater than thickness of the ST layer on the upper surface;
(f) a smooth morphology;
(g) being annealed;
(h) being substantially homogenous;
(i) the sub-surface feature having an aspect ratio that is between 1:1 and 5:1;
(j) the sub-surface feature having a width that is between 10 nm and 100 nm; and
(k) the GST film being free of surface perturbations.

83. A process of depositing a GST film, comprising providing a substrate with an upper surface and at least one sub-surface feature therein, the feature having at least a base portion and a sidewall portion; contacting the substrate with vapor phase precursors comprising Ge, Sb and Te; and depositing thereon a GST film, the GST film having a deposited thickness on at least one of the sidewall and the base portions that is greater than deposited thickness of the GST film on the upper surface of the substrate, and wherein the Ge, Sb and Te vapor phase precursors are contacted with the substrate in any order.

84. The process of claim 83, comprising vapor deposition using at least one of:
germanium methyl amide amidinate (GeMAMDN) as a germanium precursor;
tetrakis(dimethylamido)antimony, SbTDMA, as an antimony precursor; and Te(tBu)2 as a tellurium precursor.

85. The process of claim 83, comprising a vapor deposition process selected from the group consisting of chemical vapor deposition, atomic layer deposition and digital chemical vapor deposition.

86. The process of claim 83, characterized by at least one of compatible characteristics selected from the group consisting of:
(a) the GST film containing a series of layers with at least one layer constituting at least two of the elements selected from the group consisting of germanium, antimony and tellurium;
(b) the GST film containing at least two intervening germanium layers;
(c) the GST film having a smooth morphology;
(d) the GST film being a multilayer film having varying layer thickness in the multilayer film, and having an average Ge concentration of from about 1.0% to 55%; an average Sb concentration of from about 0.01% to about 70%; and an average Te concentration of from about 15% to about 55%.
(e) the GST film being annealed at least once;
(f) the GST film being substantially homogenous;
(g) the sub-surface feature having an aspect ratio that is between 1:1 and 5:1;
(h) the sub-surface feature has a width that is between 10 nm and 100 nm;
(i) the GST film is free of surface perturbations; and
(j) the GST film comprises a multi-layer structure.

87. The process of claim 83, wherein deposition temperature for the multi-layer structure is between 240° C. and 350° C.

88. The process of claim 83, wherein the GST film comprises a multi-layer structure and deposition of the multi-layer structure is carried out at deposition chamber pressure between 0.5 Torr and 20 Torr.

89. A microelectronic device structure having a sub-surface feature therein, the sub-surface feature comprising germanium, tellurium and antimony, the subsurface feature further comprising at least one superflow layer deposited therein, with a thickness that is greater in a lower portion of the subsurface feature than in an upper sidewall portion of the sub-surface feature, the superflow layer comprising at least antimony and tellurium.

90. The microelectronic device structure of claim 89, characterized by at least one of compatible characteristics selected from the group consisting of:
(a) further comprising at least one germanium containing layer;
(b) the at least one superflow layer and the at least one germanium-containing layer being in series;
(c) the germanium-containing layer being conformal;
(d) the at least one superflow layer having a thickness that is greater in a base portion of the sub-surface feature than in an upper sidewall portion of the sub-surface feature;
(e) the at least one superflow layer having a thickness that is greater in a lower sidewall portion of the sub-surface feature than in an upper sidewall portion of the sub-surface feature;
(f) having at least two superflow layers;
(g) comprising a series of layers is selected from the group consisting of:
. . . ST/G/ST/G/ST/G . . . ;
. . . GST/G/GST/G/GST . . . ;
. . . ST/G/GT/G/ST/G/GT/G . . . ;
. . . G/GST/G/GST/G/GST/G . . . ; and
. . . G/ST/G/GT/G/ST/G/GT/G . . . ;
(h) comprising at least two germanium containing layers;
(i) having a smooth morphology;

91. The microelectronic device structure of claim 89, having varying layer thickness in the superflow layer and having an average antimony concentration of from about 0.01% to about 70%, and an average tellurium concentration of from about 15% to about 55%.

92. The microelectronic device structure of claim 89, having a series of superflow layers, of varying layer thickness therein, and having an average germanium concentration of from about 1.0% to about 55%, an average antimony concentration of from about 0.01% to about 70%, and an average tellurium concentration of from about 15% to about 55%.

93. The microelectronic device structure of claim 89, further comprising at least one germanium containing layer, wherein the at least one superflow layer and the at least one germanium containing layer are in series, and wherein the series of layers are vapor deposited using germanium methyl amide amidinate (GeMAMDN) as a germanium precursor, tetrakis(dimethylamido)antimony, SbTDMA, as an antimony precursor, and Te(tBu)2 as a tellurium precursor.

94. A microelectronic device structure including a substrate and a sub-subsurface feature in said substrate, with a GST material in said sub-surface feature, including at least one superflow layer in said GST material.

95. The microelectronic device structure of claim 94, including at least one germanium layer in said GST material arranged to suppress interaction of Sb and Te.
